(19) United States
(12) Patent Application Publication
(10) Pub. No.: US 2014/0218094 A1
(43) Pub. Date: Aug. 7, 2014

(54) Method and Circuit Arrangement for Converting a Sine Wave Signal into a Square Wave Signal

(71) Applicant: Ralph Oppelt, Uttenreuth (DE)

(72) Inventor: Ralph Oppelt, Uttenreuth (DE)

(21) Appl. No.: 14/170,606

(22) Filed: Feb. 1, 2014

(30) Foreign Application Priority Data
Feb. 1, 2013 (DE) DE 102013201686.7

(51) Int. Cl. H03K 12/00

(52) U.S. Cl. CPC H03K 12/00
USPC 327/299

(57) ABSTRACT

A method for converting a sine wave signal into a square wave signal includes inputting the sine wave signal at an input of a threshold-value device that generates the square wave signal. The square wave signal is generated by comparing a sine wave signal value to a predefined threshold value, and the square wave signal is output at an output of the threshold-value device. An actuating signal is superposed on the sine wave signal at the input of the threshold-value device. The actuating signal is generated by forming an average-value signal representing an average value of the square wave signal and inputting the average-value signal at an input of a control amplifier device for generating, as the actuating signal, a signal representing a difference between an average-value signal actual value and a predefined average-value signal nominal value.

This application claims the benefit of DE 10 2013 201 686.7, filed on Feb. 1, 2013, which is hereby incorporated by reference in its entirety.

### BACKGROUND

The present embodiments relate to a method and a circuit arrangement for converting a sine wave signal into a square wave signal.

In order to convert a sine wave signal into a square wave signal, the sine wave signal may be input at an input, which is biased with a bias voltage, of a “digital buffer”, with the result that the square wave signal is generated by the buffer and is made available at the output of the buffer.

Suitable buffers for such a sine wave-square wave conversion are commercially available. By way of example, buffers are available under the trade references “74LVC1G34” (non-inverting buffer) and “74LVC1G04” (inverting buffer).

Known buffers of this type have switchover thresholds at the input that may be half the operating voltage of the buffers (e.g., +2.5 V at an operating voltage of +5 V). Without superposition of a bias voltage at the input, a sine wave voltage fed to the input via a coupling capacitor would cause the buffer output to jump to “logic 1” during the positive half-cycle and to “logic 0” during the negative half-cycle, and a square wave signal with a 50% mark-space ratio (MSR) in the following text would result on the output side. In practice, this value of the MSR is only approximately accomplished and is dependent to a certain extent on the amplitude of the sine wave signal.

If a bias voltage Ubias is fed to the input of the buffer via a bias resistor, the sine wave voltage thus “rides” on Ubias. If a sine wave voltage is fed when Ubias=+2.5 V, then nothing changes in comparison with the arrangement without a bias voltage. If, however, for example, a value Ubias =+U/2−deltaU is used, then the internal threshold of the buffer of +U/2 is only exceeded when the instantaneous value of the sine wave voltage exceeds +deltaU. Thus, the MSR may be controlled about the normal 50% operating point by a variable predefinition of the bias voltage Ubias at a given amplitude of the sine wave voltage. However, the MSR would still change in the event of a changing sine wave amplitude.

This method involves comparing the sine wave signal value and a predefined threshold value (e.g., dependent on the internal buffer threshold and the bias voltage) using a “threshold-value device” (e.g., buffer with connection to bias voltage), and the square wave signal is generated as a result of this comparison. As an alternative to a buffer, the threshold-value device may also be formed, for example, from a comparator with two inputs. The sine wave signal is fed to one input, and a reference signal (e.g., comparison voltage) is fed to the other input.

It is disadvantageous in the case of the prior art that the mark-space ratio (MSR) of the square wave signal obtained in this way is dependent on the amplitude of the sine wave signal to be converted, which is unwanted in many applications. There is therefore no possibility of adjusting the MSR to a predefinable fixed value.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a way of converting a sine wave signal into a square wave signal, in which the MSR of the square wave signal is as independent as possible of the amplitude of the sine wave signal and the MSR may be adjusted is provided.

The conversion method according to one or more of the present embodiments includes superimposing an actuating signal on the sine wave signal at the input of the threshold-value device. The actuating signal is generated by forming an average-value signal representing the average value of the square wave signal. The conversion method also includes inputting an average-value signal at an input of a control amplifier device for generating, as the actuating signal, a signal representing a difference between an average-value signal actual value and a predefined average-value signal nominal value.

The circuit arrangement according to one or more of the present embodiments includes an average-value forming device for forming an average-value signal representing the average value of the square wave signal, and a control amplifier device, into which the average-value signal may be input at an input for generating, as the actuating signal, a signal representing a difference between an average-value signal actual value and a predefined average-value signal nominal value.

In an embodiment, the average-value forming device and the control amplifier device are combined to give one integral control amplifier device.

The MSR of a square wave signal is directly proportional to the average value of the square wave signal. On this basis, a targeted influence is provided by superposing an additional actuating signal at the input of the threshold-value device such that the average value of the square wave signal, equivalent to the MSR, is adjusted to a predefined value. For this purpose, according to one or more of the present embodiments, control, in which an “actual signal” (e.g., representative of the average value or the MSR) is formed by forming an average-value signal representing the average value of the square wave signal, is provided. The average-value signal serves as a basis for generating the actuating signal. The actuating signal is in this case generated by the control amplifier device as the (amplified) difference between the average-value signal actual value and a predefined average-value signal nominal value. Correspondingly, in the case of a control deviation (i.e., a difference between actual value and nominal value), the control deviation is counteracted such that the actual value is matched to the nominal value.

Advantageously, in the case of one or more of the present embodiments, the influence of the sine wave signal amplitude on the MSR of the generated square wave signal disappears. The resulting MSR is easily predefinable (e.g., by appropriate predefinition of the average-value signal nominal value).

In an embodiment or use of the embodiment, a sine wave signal with an amplitude of less than 5 Vss (e.g., less than 2 Vss) is converted.

The frequency of the sine wave signal may be, for example, greater than 10 MHz (e.g., greater than 100 MHz).

The square wave signal may have an amplitude of, for example, more than 2 Vss (e.g., more than 5 Vss).

According to a further aspect, the conversion method or the conversion circuit arrangement is used in order to reverse the polarity of a switching mixer using the generated square wave signal. For example, for this use of the signal conversion, it is advantageous for control to occur to adjust the MSR of the square wave signal to at least approximately 50% (e.g., in the range from 45 to 55%). A very precise adjustment of the MSR in this range is advantageously enabled by one or more of the present embodiments.

With regard to circuitry, the threshold-value device may be provided, for example, as one or more CMOS logic chips (e.g., buffer, comparator, processor or the like). If buffers are used, a bias voltage (e.g., bias) may be realized, for example, by applying at least one bias voltage via a respective electrical resistor to the at least one input of the threshold-value device. If comparators are used, a respective reference voltage (e.g., for the comparison with the sine wave signal actual value) may also be directly applied at the relevant input (e.g., reference input).

To input the sine wave signal at the input of the threshold-value device, the arrangement of at least one coupling-in capacitor may be provided.

To form the average-value signal, a low-pass filter or integrator, the time constant (e.g., RC time constant) of which is substantially larger (e.g., by one or more powers of ten) than the oscillation period of the sine wave signal, may be used. In the event of a varying frequency of the sine wave signal, the oscillation period of the lowest-frequency signal component is decisive for this purpose.

### BRIEF DESCRIPTION OF THE DRAWINGS

FIG. 1 illustrates a circuit diagram of a FET bridge mixer with peripheral wiring and basic LO signal profile;

FIG. 2 illustrates a circuit diagram of a FET bridge mixer with conventional circuit arrangement, connected upstream, for conversion of a sinusoidal LO signal into a square LO signal, by which the FET bridge mixer is actuated;

FIG. 3 illustrates a circuit diagram of a circuit arrangement for converting a sine wave signal into a square wave signal, according to an embodiment;

FIG. 4 illustrates a circuit diagram to exemplify predefinition of an MSR in the branch of a non-inverting buffer by an inverting integral controller, according to a further embodiment; and

FIG. 5 illustrates a circuit diagram to exemplify predefinition of an MSR in the branch of an inverting buffer by a non-inverting integral controller, according to the further embodiment.

### DETAILED DESCRIPTION

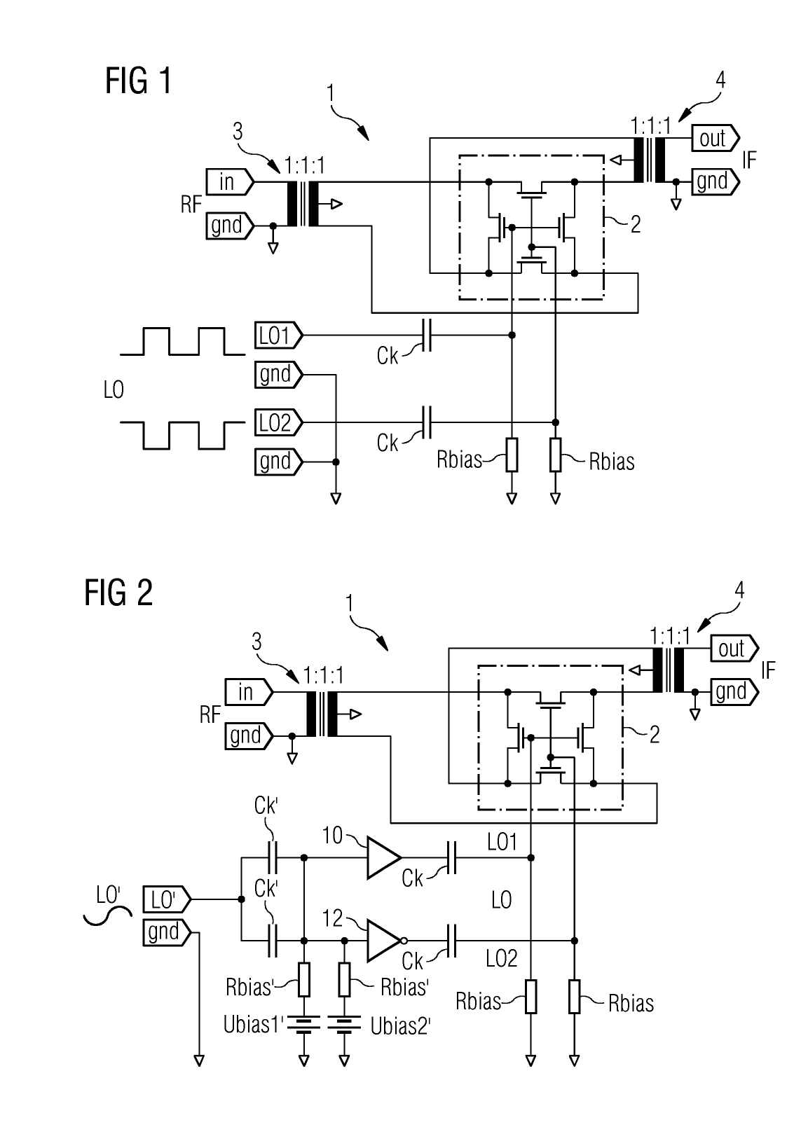

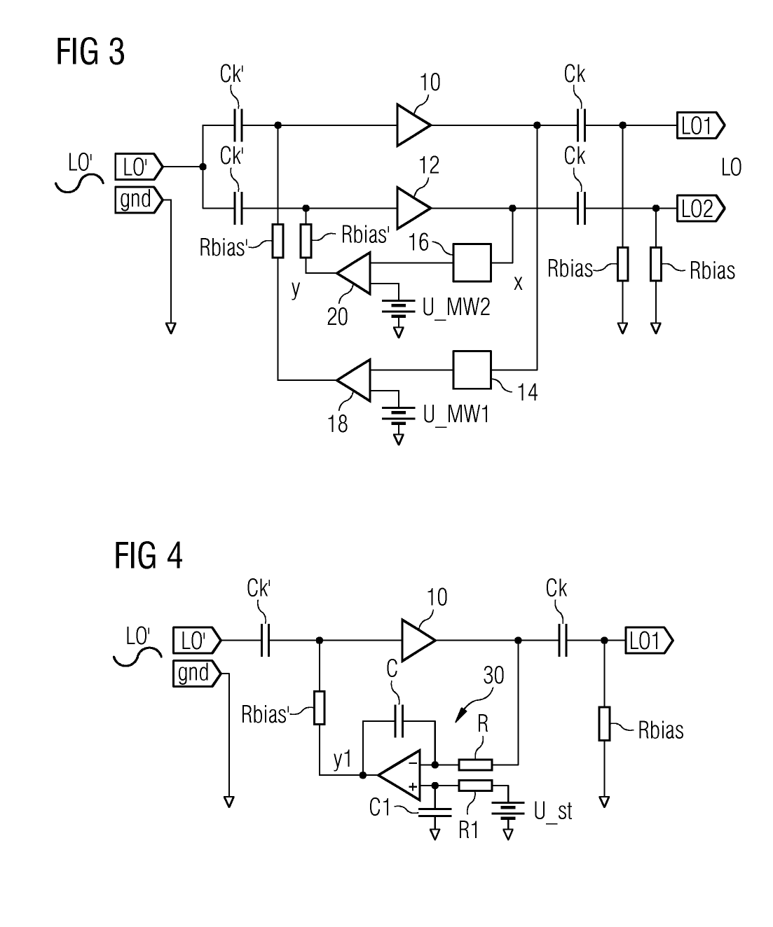

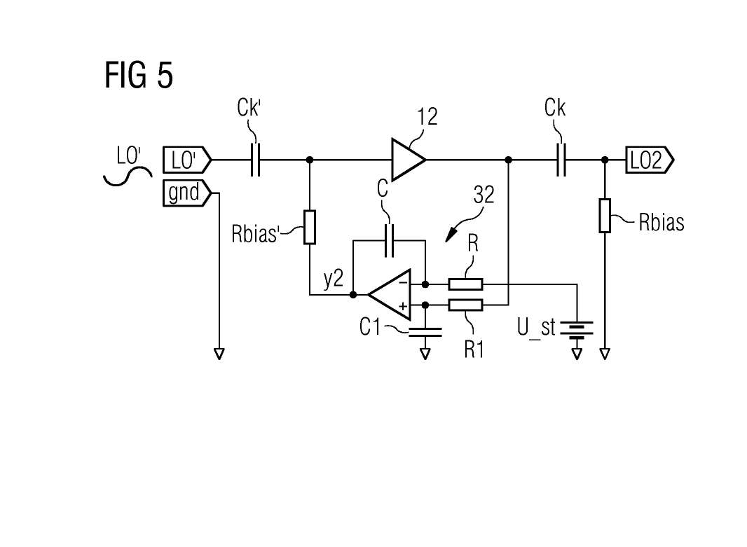

Before a signal conversion according to one or more of the present embodiments is discussed further with reference to FIG. 3 or to FIGS. 4 and 5, the problem on which the invention is based will first be explained in a little more detail with reference to FIGS. 1 and 2.

FIG. 1 shows a typical construction of a switching mixer (e.g., a FET bridge mixer 1) for mixing (e.g., frequency mixing) a first electrical signal RF with a second electrical signal LO and outputting a resultant signal IF.

The FET bridge mixer 1 includes a FET arrangement 2, as illustrated, and peripheral wiring (e.g., transformers 3 and 4) for impedance conversion (and conversion into a differential signal) in the path of the first input signal RF and in the path of the output signal IF.

The second input signal LO may be termed local oscillator signal (“LO signal”). For switching mixers (e.g., diode-ring mixers, FET bridge mixers), square wave signals may be required here (e.g., with relatively large amplitude). In the illustrated example, the square LO signal is used to reverse the polarity of the FETs in the FET arrangement 2. FET bridge mixers of the type illustrated in FIG. 1 may be optimum for good intermodulation values with a simultaneously low power demand for the LO signal.

In the illustrated example, the signal LO is fed in differential form to connections LO1 and LO2 (in each case with reference to electrical ground “gnd”) of the FET bridge 2.

As illustrated, coupling-in capacitors Ck are arranged in the input path, and bias resistors Rbias are arranged going out from the input path to electrical ground gnd. The time constant resulting from the values of Ck and Rbias is measured such that the lowest frequency of the signal LO may pass practically undamped (e.g., separation of HF and DC components).

It is shown that, depending on the state of the signal LO, alternately different pairs of FETs of the FET arrangement 2 are switched on. The respective other FET pair is switched off. The mixer input signal RF therefore appears to reverse in polarity in rhythm with the signal LO at the mixer output (e.g., signal IF). Only the sum and differential frequencies of the spectral components of the signals LO and RF may appear at the output, and not the original spectra. This is referred to as input or LO signal suppression, which may be 50 dB and more in the case of high-quality mixers. A high LO suppression is provided because, for example, phase noise of the signal LO may impair the signal/noise ratio of the mixer output signal IF if LO frequency and IF frequency are spectrally near to one another. It is known from the theory of switching mixers that even the spectral proximity of an odd-numbered harmonic to the LO fundamental frequency may contribute to such an impairment.

However, a practical problem includes that local oscillator signals may not be in the preferred square wave shape (i.e., with relatively steep rising and falling edges) on the generator side, but rather are sinusoidal (i.e., with relatively flat rising and falling edges). In addition, LO signals may have a relatively small amplitude (e.g., approximately 1 Vss).

A solution to this problem known from the prior art (e.g., for square wave conversion (and simultaneous amplification) of the LO signal) includes converting an input signal that was originally generated as a sine wave signal LO′ into a square wave signal LO using one or more buffer chips, as is illustrated in FIG. 2.

FIG. 2 exemplifies the actuation of the FET bridge mixer 1 with CMOS buffers 10 and 12 for a sinusoidally fed input signal LO′. The buffers 10, 12 may be embodied as CMOS buffers of the “74LVC logic” family, for example. Hence, square voltages LO (e.g., difference between the voltages LO1 and LO2) with an amplitude of approximately 10 Vss may be generated, for example, very simply for frequencies of the signal LO′ of up to approximately 300 MHz, and may be fed to the FET arrangement 2.

In the example illustrated in FIG. 2, the buffer 10 is a non-inverting buffer chip, and the buffer 12 is an inverting buffer chip (e.g., of the type 74 LVC1G04 and, respectively, LVC1G34).

Together with the wiring illustrated in FIG. 2, the buffers 10, 12 form a threshold-value device, into which the sine wave signal LO′ is input, and which generates the square wave signal LO by comparing the sine wave signal value to a predefined threshold value and outputs (e.g., for input as polarity-reversal signal for the FET bridge mixer 1) the square wave signal. The “threshold value” is predefined in this case by the bias voltages Ubias1′, Ubias2′, in connection with the fixedly predefined internal buffer thresholds (as already mentioned at the outset). The bias voltages Ubias1′, Ubias2′ are applied via a respective coupling-in resistor Rbias′ to the input of the respective buffer 10 or 12. At the same time, the sine wave signal LO′ is fed, as illustrated in FIG. 2, via coupling-in capacitors Ck′ to the inputs of the buffers 10, 12 or to the input of the “threshold-value device”.

In the illustrated exemplary embodiment, the potentials at the buffer outputs change each time the threshold value is exceeded or the threshold value is exceeded (e.g., between “logic 1” and “logic 0” or vice versa).

The wiring on the output side of the buffers 10, 12, between the outputs of which the signal LO converted into a square wave is present or is output, corresponds to the wiring already illustrated in FIG. 1 (e.g., coupling capacitors Ck and bias resistors Rbias).

Advantageously, in the case of the circuit arrangement from FIG. 2, a square wave signal (e.g., signal LO) is thus provided for reversing the polarity of the FETs of the FET arrangement 2.

However, in the case of the circuit arrangement from FIG. 2, it is disadvantageous that the exact mark-space ratio (MSR) of the square wave signal LO obtained in this way is dependent on the amplitude of the sine wave signal LO′ to be converted.

In order to eliminate this problem, a modified circuit arrangement for converting a sine wave signal into a square wave signal is provided, as is illustrated by way of example in FIG. 3.

FIG. 3 shows one embodiment of a circuit arrangement similar to that in FIG. 2. In the circuit arrangement of FIG. 3, however, an individual adjustment of the output-side MSR is enabled for the two LO signal branches that conduct the differential LO signal in this example. In addition, it is advantageous in the configuration according to FIG. 3 that the MSR of the output signal LO does not change if the LO′ input level changes.

The circuit arrangement according to FIG. 3 works as follows. On the output side, the buffers 10, 12 continuously periodically alternate back and forth between the supply voltage +U (e.g., 5 V) thereof and 0 V (e.g., ground). The average value of the square wave signal output from each of the buffers is directly proportional to the output-side MSR. A 50% ratio corresponds, for example, to an average value of the signals LO1 and LO2 of +U/2.

In the case of the circuit from FIG. 3, the MSR of the signals LO1 and L02, and therefore of the signal LO, is predefined by superposing an actuating signal y on the sine wave signal LO′ at the input of the threshold-value device formed by the buffers 10, 12. The actuating signal is generated by forming an average-value signal x, representing the average value of the square wave signal LO, by two average-value formers 14, 16 in the illustrated example, and inputting the average-value signal x at an input of a control amplifier device (e.g., including control amplifiers 18, 20) for generating, as the actuating signal y, a signal representing a difference between an average-value signal actual value (e.g., signal x) and a predefined average-value signal nominal value.

In the illustrated example, the average-value signal nominal value (e.g., reference variable for adjusting the MSR) is defined by reference voltages U_MW1 and U_MW2 that are generated in a manner suitable for this purpose and, as illustrated, are input to the second or “nominal value” input of the control amplifiers 18, 20.

In other words, the MSR of the square wave signal LO is predefined by tying, by a controller, the average value of the signal LO to a predefined nominal value (e.g., predefined by the reference voltages U_MW1 and U_MW2). The input or the bias voltage of the buffer chips 10, 12 (e.g., threshold-value device) is used as actuator of the control. The varying MSR at the output, in the case of sinusoidal actuation (e.g., signal LO′) with varying amplitude in the known circuit arrangement, is in this way advantageously controlled to a desired value. Owing to the relatively high control amplification, the MSR then remains as constant as possible, even in the event of a changing amplitude of the input signal LO′.

Each of the average-value formers 14, 16 may be embodied, for example, as a low-pass filter or integrator, the characteristic time constant (“RC time constant”) of which is significantly (e.g., by at least one power of ten or at least two powers of ten) longer than the oscillation period of the lowest oscillation component of the LO signal.

In one embodiment, an integral controller device that combines the functions of the average-value forming device (e.g., two average-value formers with differential signal routing; processors) and the control amplifier device (e.g., two control amplifiers with differential signal routing) is provided. A corresponding exemplary embodiment is described below with reference to FIGS. 4 and 5. In the embodiment, an integral controller device of this type is used.

FIG. 4 exemplifies the MSR predefinition in the branch of the non-inverting buffer 10 using an inverting integral controller 30.

As illustrated in FIG. 4, the integral controller 30 is formed from an operational amplifier with suitable external wiring. The LO1 signal is applied via a resistor R to the inverting input of the operational amplifier. The inverting input is connected via an integration capacitor C to the output of the operational amplifier. The other, non-inverting input of the operational amplifier is connected via a further capacitor C1 to ground and via a further resistor R1 to a voltage source for inputting a reference voltage U_st (e.g., which defines the average-value signal nominal value for the signal L01). The low-pass member formed from R1 and C1 is used to filter a possibly non-ideal reference voltage U_st (e.g., in the case of superposed noise or other high-frequency interference components) and may also be omitted in the case of an appropriately clean reference voltage. In this case, the capacitor C1 may be omitted. R1 may remain or be replaced with a low-impedance line connection in order to apply the reference voltage U_st directly to the non-inverting input of the operational amplifier. The output signal y1 of the operational amplifier is conducted via a coupling-in or superposition resistor Rbias′ to the input of the buffer chip 10. Therefore, the superposition of the actuating signal y1 on the fed sine wave signal LO′ takes place at the input.

The MSR of the signal LO1 may therefore be adjusted via the reference voltage U_st applied (e.g., in accordance with an average-value signal nominal value) to the non-inverting input of the operational amplifier.

An analysis of the integral controller 30 along with the wiring reveals that the control deviation LO1-U_st is fed back to the input of the buffer 10 amplified and with the correct mathematical sign, in order to implement the required control functionality.

The circuit illustrated in FIG. 4 is therefore a more specific embodiment of the controller branch formed in FIG. 3 from the average-value former 14 and the control amplifier 18 for the non-inverting buffer 10.

However, the circuit according to FIG. 4 may not be used for the inverting buffer 12, since the “reverse integrator” 30 would then lead to positive feedback (instead of negative feedback). One possibility for implementing the negative feedback may be to insert a further operational amplifier connected as reverse amplifier upstream or downstream of the reverse integrator 30 illustrated in FIG. 4. In one embodiment, the MSR in the branch of the inverting buffer 12 is predefined using a non-inverting integral controller 32, as is illustrated in FIG. 5, for example.

The non-inverting integral controller 32 is also formed from an operational amplifier with external wiring. A reference voltage U_st defining the average-value signal nominal value is led via a resistor R to the inverting input of the operational amplifier. The inverting input is connected via an integration capacitor C to the output of the operational amplifier. The other, non-inverting input of the operational amplifier is connected via a further resistor R1 to the output of the buffer 12 and via a further capacitor C1 to ground. The output of the operational amplifier is connected via a coupling-in or superposition resistor Rbias′ to the input of the buffer 12.

An analysis of the integral controller 32 again reveals that, in the case of suitable wiring (R1C1=RC) for DC voltages, the control deviation LO2-U_st is virtually limitlessly amplified in a desirable manner and fed back with the correct mathematical sign to the input of the inverting buffer 12. However, higher frequency components are not negatively fed back to any appreciable extent.

The circuit illustrated in FIG. 5 is therefore a specific embodiment of the feedback branch formed in FIG. 3 from the average-value former 16 and the control amplifier 20.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for converting a sine wave signal into a square wave signal, the method comprising:
inputting the sine wave signal at an input of a threshold-value device that generates the square wave signal by comparing a sine wave signal value to a predefined threshold value and outputs the square wave signal at an output of the threshold-value device; and
superimposing an actuating signal on the sine wave signal at the input of the threshold-value device, the actuating signal being generated by:
forming an average-value signal representing an average value of the square wave signal; and
inputting the average-value signal at an input of a control amplifier device for generating, as the actuating signal, a signal representing a difference between an average-value signal actual value and a predefined average-value signal nominal value.

2. A circuit arrangement for converting a sine wave signal into a square wave signal, the circuit arrangement comprising:
a threshold-value device, into which the sine wave signal is inputtable at an input, the threshold-value device configured to generate the square wave signal by comparing a sine wave signal value to a predefined threshold value and output the generated square wave signal at an output of the threshold-value device;
an average-value forming device configured to form an average-value signal representing a average value of the square wave signal; and
a control amplifier device, into which the average-value signal is inputtable at an input, the control amplifier device configured for generating, as an actuating signal, a signal representing a difference between an average-value signal actual value and a predefined average-value signal nominal value.

3. A method comprising:
inputting a sine wave signal at an input of a threshold-value device;
generating, with the threshold-value device, the square wave signal, the generating comprising comparing a sine wave signal value to a predefined threshold value;
outputting the square wave signal at an output of the threshold-value device;
superimposing an actuating signal on the sine wave signal at the input of the threshold-value device, the actuating signal being generated by:
forming an average-value signal representing an average value of the square wave signal; and
inputting the average-value signal at an input of a control amplifier device for generating, as the actuating signal, a signal representing a difference between an average-value signal actual value and a predefined average-value signal nominal value; and
reversing polarity of a switching mixer with the square wave signal.
